(19) United States
(12) Patent Application Publication
(10) Pub. No.: US 2026/0053007 A1
(43) Pub. Date: Feb. 19, 2026

(54) Package with Thinner and Thicker Carriers for Carrying and Connecting Electronic Component

(71) Applicant: Infineon Technologies Austria AG, Villach (AT)

(72) Inventors: Marlon David Bartolo, Concolacion (PH); Nurul Farhana Ibrahim, Kulim (MY); Chee Voon Tan, Seremban (MY); Mohd Hirzarul Hafiz Mohd Tahir, Bukit Rambai (MY); Xue Yang, Tianshui 260 CN (CN)

(21) Appl. No.: 19/294,595

(22) Filed: Aug. 8, 2025

(30) Foreign Application Priority Data
Aug. 14, 2024 (DE) 102024123275.7

(51) Int. Cl. H01L 23/495; H01L 21/48; H01L 21/56; H01L 23/00; H01L 23/538; H01L 25/18; H10D 80/30

(52) U.S. Cl. CPC H01L 23/49541; H01L 21/4828; H01L 23/49503; H01L 23/5385; H01L 25/18; H10D 80/30; H01L 21/56; H01L 24/48; H01L 2224/48245

(57) ABSTRACT

A package includes a first carrier including a component mounting area, a second carrier including at least one lead section, at least one electronic component mounted on the component mounting area, and an encapsulant encapsulating at least part of the at least one electronic component, encapsulating at least part of the first carrier including encapsulating the entire sidewalls of the first carrier, and encapsulating part of the second carrier, wherein the first carrier is assembled with the second carrier so that the at least one electronic component and/or the first carrier is electrically connected with the at least one lead section, and wherein the first carrier has a first thickness and the second carrier has a second thickness being smaller than the first thickness.

### TECHNICAL FIELD

Various embodiments relate generally to a package, and a method of manufacturing a package.

### BACKGROUND

Packages may be denoted as encapsulated electronic components with electrical connections extending out of the encapsulant and being mountable on an electronic periphery, for instance on a printed circuit board.

Packaging cost is an important driver for the industry. Related with this are performance, dimensions and reliability. The different packaging solutions are manifold and have to address the needs of the application.

### SUMMARY

There may be a need to provide a possibility to manufacture packages with high reliability and performance and in a simple and quick way with reasonable effort.

According to an exemplary embodiment, a package is provided which comprises a first carrier comprising a component mounting area, a second carrier comprising at least one lead section, at least one electronic component mounted on the component mounting area, and an encapsulant encapsulating at least part of the at least one electronic component, encapsulating at least part of the first carrier including encapsulating the entire sidewalls of the first carrier, and encapsulating part of the second carrier, wherein the first carrier is assembled with the second carrier so that the at least one electronic component and/or the first carrier is electrically connected with the at least one lead section, and wherein the first carrier has a first thickness and the second carrier has a second thickness being smaller than the first thickness.

According to another exemplary embodiment, a method of manufacturing a package is provided, wherein the method comprises providing a first carrier comprising a component mounting area, providing a second carrier comprising at least one lead section, mounting at least one electronic component on the component mounting area, assembling the first carrier with the second carrier so that the at least one electronic component and/or the first carrier is electrically connected with the at least one lead section, wherein the first carrier has a first thickness and the second carrier has a second thickness being smaller than the first thickness, and encapsulating at least part of the at least one electronic component, encapsulating at least part of the first carrier including encapsulating the entire sidewalls of the first carrier, and encapsulating part of the second carrier by an encapsulant.

According to an exemplary embodiment, a package (such as a semiconductor power package) combines two different carriers, i.e. a first carrier and a second carrier (for instance two leadframes structures). The first carrier may be equipped with a component mounting area, which may be a die pad. The second carrier may comprise a lead section, which may provide the package with one or more leads which can be accessed at an exterior of the package for establishing an electric connection with an electronic environment. One or electronic component(s), such as a semiconductor chip, may be assembled on the component mounting area of the first carrier. An encapsulant (for example a mold compound) may encapsulate the one or more electronic components. Moreover, said encapsulant may encapsulate the first carrier including its entire sidewalls, so that no sidewall portions of the first carrier are exposed with respect to the encapsulant. In addition, the encapsulant may also partially encapsulate the second carrier, for instance in such a way that the at least one lead section is exposed with respect to the encapsulant for establishing an electric connection of the package with an electronic environment. Advantageously, the first carrier may be electrically and mechanically connected with the second carrier for establishing an electric connection between the electronic component and/or the first carrier with the lead section of the second carrier. Beneficially, the first carrier can be provided with a larger thickness than the second carrier. This has advantages: The relatively thick first carrier can carry even a very big electronic component (such as a very big gallium nitride die) without the risk of excessive warpage (in particular during a reflow process). At the same time, the relatively thin second carrier may provide tiny leads with well-defined properties at its lead section. A further advantage may be that the thicker first carrier may be beneficial for heat dissipation, especially via its bottom surface which may be exposed at the bottom surface of the package. Furthermore, the thinner second carrier can have more tiny leads than a thicker carrier, due to the fact that for example a thinner leadframe can have smaller lead pitch between two adjacent leads. Therefore, for the same size, a thinner leadframe can have more leads than a thicker leadframe. In a nutshell, the described packaging architecture may combine two carriers or substrates with different thicknesses. The thinner second carrier may enable high pin count and/or excellent lead pitches, which may be particularly advantageous for a package configured as power stage, half-bridge or multi-chip package. Simultaneously, the thicker first carrier may enable the use of a big electronic component (such as big gallium nitride semiconductor chip), which may provide excellent performance of the package (in particular for power applications). Encapsulating the entire sidewalls of the first carrier by the encapsulant may be in particular possible since the at least one lead section of the second carrier may be at least partially exposed with respect to the encapsulant and may allow to electrically contact the electronic component assembled on the first carrier. Thus, the sidewalls of the first carrier may be fully encapsulated and thereby protected by the encapsulant.

### BRIEF DESCRIPTION OF THE DRAWINGS

The accompanying drawings, which are included to provide a further understanding of exemplary embodiments and constitute a part of the specification, illustrate exemplary embodiments.

The illustration in the drawing is schematically and not to scale.

In the drawings:

FIG. 1 illustrates a three-dimensional top view of a package according to an exemplary embodiment without encapsulant.

FIG. 2 illustrates a three-dimensional bottom view of the package according to FIG. 1 without encapsulant.

FIG. 3 illustrates a three-dimensional top view of the package according to FIG. 1 with encapsulant.

FIG. 4 illustrates a three-dimensional bottom view of the package according to FIG. 1 with encapsulant.

FIG. 5 illustrates a three-dimensional top view of a first carrier of the package according to FIG. 1.

FIG. 6 illustrates a three-dimensional bottom view of the first carrier according to FIG. 5.

FIG. 7 illustrates a three-dimensional top view of a second carrier of the package according to FIG. 1.

FIG. 8 illustrates a three-dimensional bottom view of the second carrier according to FIG. 7.

FIG. 9 illustrates an arrangement of second carriers used during a batch process of manufacturing packages according to an exemplary embodiment.

FIG. 10 illustrates an arrangement of first carriers used during a batch process of manufacturing packages according to an exemplary embodiment.

FIGS. 11 to 21 illustrate structures obtained during manufacturing packages according to an exemplary embodiment in a batch manufacturing process.

### DETAILED DESCRIPTION

In the following, further exemplary embodiments of the package, and the method will be explained.

In the context of the present application, the term “package” may particularly denote an electronic device which may comprise one or more electronic components mounted on a carrier. Said constituents of the package may be encapsulated at least partially by an encapsulant. Optionally, one or more electrically conductive interconnect bodies (such as bond wires and/or clips) may be implemented in a package, for instance for electrically coupling the electronic component with the carrier and/or with leads.

In the context of the present application, the term “carrier” may particularly denote a support structure (which may be at least partially electrically conductive) which serves as a mechanical support for the one or more electronic components to be mounted thereon, and which may also contribute to the electric interconnection between the electronic component(s) and the periphery of the package. In other words, the carrier may fulfil a mechanical support function and an electric connection function. A carrier may comprise or consist of a single part, multiple parts joined via encapsulation or other package components, or a subassembly of carriers.

In the context of the present application, the term “component mounting area” may particularly denote a section of the carrier which is configured for mounting at least one electronic component thereon. For instance, the component mounting area may be a die pad. In an embodiment, the component mounting area may be a planar plate-like metallic body or region.

In the context of the present application, the term “lead section” may particularly denote an electrically conductive (for instance strip shaped) element (which may be planar or bent) which serves for contacting the electronic component and/or a carrier with an exterior of the package. For instance, a lead section may be partially encapsulated and partially exposed with respect to an encapsulant. When the carrier forms part of a leadframe, leads or lead sections may surround a die pad, for instance at two opposing sides or at all four sides. The one or more lead sections may or may not form part of the carrier.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), a light emitting, semiconductor-based device (such as a light emitting diode (LED) or LASER), an actuator (for instance a loudspeaker), and a microelectromechanical system (MEMS). In particular, the electronic component may be a semiconductor chip having at least one integrated circuit element (such as a diode or a transistor) in a surface portion thereof. The electronic component may be a naked die or may be already packaged or encapsulated. Semiconductor chips implemented according to exemplary embodiments may be formed in silicon technology, gallium nitride technology, silicon carbide technology, etc.

In the context of the present application, the term “encapsulant” may particularly denote a substantially electrically insulating material surrounding at least part of an electronic component and at least part of a carrier to provide mechanical protection, electrical insulation, and optionally a contribution to heat removal during operation. In particular, said encapsulant may be a mold compound. A mold compound may comprise a matrix of flowable and hardenable material and filler particles embedded therein. For instance, filler particles may be used to adjust the properties of the mold component, in particular to enhance thermal conductivity.

In the context of the present application, the term “the first carrier is assembled with the second carrier” may particularly denote that the first carrier and the second carrier are separate bodies or structures which are connected with each other electrically and/or mechanically.

In the context of the present application, the term “thickness of a carrier” may particularly denote a vertical extension of the respective carrier, which may be a structured plate. In particular, the thickness of the carrier may denote a maximum thickness of the carrier.

In the context of the present application, the term “main surface” of a body may particularly denote a largest body surface of one of the largest body surfaces. For instance, a body (such as a carrier or an electronic component or part thereof) may be plate-shaped or substantially plate-shaped and may then have two opposing main surfaces separated by body material in a thickness direction and connected with each other by a circumferential edge.

In an embodiment, the first carrier has a first thickness in a range from 300 μm to 1 mm, in particular in a range from 400 μm to 700 μm. Such a large thickness may ensure that an even very big electronic component, such as a big gallium nitride die, can be assembled on the first carrier without the risk of excessive bending or warpage. It may also be advantageous that a thicker carrier is better for heat dissipation.

In an embodiment, the second carrier has a second thickness in a range from 50 μm to 300 μm, in particular in a range from 150 μm to 300 μm. With such a small thickness, leads with high pin count can be manufactured with high quality and/or high numbers.

In an embodiment, the first carrier is assembled with the second carrier by an electrically conductive connection medium, in particular a solder, a sinter material and/or electrically conductive glue. The connection medium may be a material which may be configured for, preferably mechanically and electrically, connecting different constituents with each other. Examples for a connection medium are a solder, a glue or an assembly adhesive, or even a sinterable or semi-sinterable material.

In an embodiment, the first carrier comprises a patterned and/or bent metal plate, in particular a leadframe structure. In an embodiment, the second carrier comprises a patterned and/or bent metal plate, in particular a leadframe structure. The respective plate may be planar or curved and/or patterned or structured. The respective plate may have a constant thickness, may have different regions of different thicknesses, or may have a gradually varying thickness. In the context of the present application, the term “leadframe” may particularly denote a metal structure comprising an array of initially integrally connected carriers and leads for packages. The electronic component(s) may be attached to the carriers of the leadframe, and then bond wires and/or clips may be provided for attaching pads of the electronic component to leads of the leadframe. Subsequently, the leadframe may be molded in a plastic case or any other encapsulant. Outside and/or inside of the leadframe, corresponding portions of the leadframe may be cut-off, thereby separating the respective leads and/or carriers. A leadframe may be composed of multiple carriers, wherein each carrier may have a component mounting area and/or one or more leads or lead sections.

In an embodiment, the second carrier is formed as frame structure. In particular, the second carrier may have a frame shape with an opening in which at least part of the first carrier is accommodated. Such an opening may be surrounded by a metallic frame which provides mechanical support and may also include leads of the lead section. Said opening may be shaped and dimensioned so as to be capable of accommodating the first carrier therein which may provide a component mounting area with higher thickness. This additive formation of a common body based on two carriers with different and functionally cooperating properties in terms of low-warpage component assembly and provision of leads with high lead count may result in a package being easily manufacturable and having a high performance.

In an embodiment, the first carrier is free of lead sections. Thus, the function of the first carrier may be substantially limited to carrying at least one electronic component without the risk of excessive warpage or bending without the need of contributing to lead formation. This may result in a compact design of the first carrier and of the package as a whole. In another embodiment, it may however also be possible that the first carrier also includes one or more lead sections.

In an embodiment, the second carrier comprises a further component mounting area on which at least one further electronic component is mounted. Thus, in addition to the component mounting area of the first carrier, also the second carrier may provide the additional capability of mounting one or more further electronic components thereon. This may allow the formation of a multi-component package. However, it may be preferred that the electronic component mounted on the component mounting area of the thicker first carrier is bigger than the at least one further electronic component mounted on the further component mounting area of the thinner second carrier to suppress warpage while keeping the design contact.

In an embodiment, the at least one further electronic component comprises a logic chip. For instance, such a further electronic component may be a controller chip or a driver chip. Such a controller or driver chip may control or drive a power semiconductor chip. The electronic component mounted on the component mounting area of the first carrier may be such a semiconductor power chip.

In an embodiment, the first carrier has a thicker central portion at least partially surrounded by a thinner peripheral portion. Thus, the first carrier may be formed with different thickness portions having at least one step in between. The top surface of the thicker central portion and the thinner peripheral portion may relate to the component mounting area, which may be advantageous for a big electronic component, and/or advantageous for avoiding warpage of the electronic component. The thinner peripheral portion may be configured for being connected with the second carrier, in particular with a frame structure or a lead section of the second carrier. This connection may at least partially compensate a thickness difference between the first carrier and the second carrier and may lead to a relatively planar carrier combination from the bottom view.

In an embodiment, the thinner peripheral portion of the first carrier is connected with the second carrier. Advantageously, this may lead to a reliable connection between the first carrier and the second carrier, since the inter-carrier connection can be made via for example one, two, three or even four sides of the first carrier. The connection via a thinner peripheral portion of the first carrier may be advantageously combined with a frame-shaped second carrier. Also height differences between first carrier and second carrier may be compensated partially or entirely by such a configuration.

In an embodiment, the thinner peripheral portion of the first carrier is assembled with the second carrier so that the at least one lead section and the thicker central portion are coplanar (more specifically, are coplanar from the bottom surface of the package). For example, a main surface of the first carrier opposing the component mounting area of the first carrier on which at least one electronic component may be assembled may be coplanar with a main surface of leads of the lead section of the second carrier. After encapsulation by an encapsulant, the above-mentioned main surface of the first carrier may be exposed at a main surface of the package. The coplanar parts may be said exposed main surface of the first carrier and said main surface of the leads of the lead section of the second carrier. Thus, these electrically and thermally conductive surfaces of the first carrier and the second carrier may be at the same vertical level where exposed with respect to the encapsulant. This may simplify assembly of the package as a whole on a mounting base (such as a printed circuit board) or on a heat sink (such as an electrically conductive plate with a plurality of cooling fins extending therefrom). Optionally but advantageously, component-opposing surfaces of one or more further component mounting areas of the second carrier may also be exposed on the same main surface of the package as the above mentioned coplanar elements, and may be preferably also coplanar with said elements.

In an embodiment, the at least one electronic component comprises at least one of the group consisting of a gallium nitride chip, a semiconductor power chip, a transistor chip, a half-bridge chip, a driver chip, a logic chip, and a controller chip. However, many different kinds of electronic components may be assembled at the carrier of exemplary embodiments. Preferably, the at least one electronic component may be a lateral die. A current flow during operation may be substantially horizontally. However, it may also be possible that the at least one electronic component is a die experiencing vertical current flow during operation.

In an embodiment, the at least one electronic component comprises at least two electronic components belonging to two different chip categories, for example a power chip and a logic chip. These two components may belong to two different categories of chips, one being a power chip and another one being a logic chip. For instance, the power chip may be bigger than the logic chip. The power chip may for instance be a gallium nitride chip. For example, the logic chip may be a controller chip or driver chip controlling the power chip. Other configurations are however possible. In particular, a power chip and a logic chip may be mounted on the first carrier, whereas a further logic chip may be mounted on the second carrier. These three chips may be interconnected.

In an embodiment, at least part of the at least one lead section is exposed with respect to the encapsulant at least at a sidewall and/or a bottom surface of the package. When exposed with respect to the encapsulant, an electric connection of the exposed portions of the lead section may allow electric access to the one or more electronic components assembled in an interior of the encapsulant. Since access to the encapsulated electronic component(s) is enabled via the exposed lead(s) of the at least one lead section, it is in particular possible that the entire sidewalls of the first carrier are fully covered by encapsulant material.

In an embodiment, a bottom surface of the first carrier opposing the component mounting surface is exposed at the bottom of the package. In other words, one of two opposing main surfaces of the component mounting area may be at least partially exposed with respect to the encapsulant. Such an exposed main surface of the first carrier's component mounting area may allow to efficiently remove heat generated by the at least one electronic component during operation of the package. Since the first carrier may be made partially or entirely from a metallic material which may also have a high thermal conductivity, heat removal by an exposed first carrier surface may be much more efficient than through material of the encapsulant, having usually a significantly lower thermal conductivity than the carrier. When the first carrier is exposed with respect to the encapsulant at one main surface of the package, an exposed electrically conductive surface may be provided which may simplify electrically connecting the package and which may also promote heat dissipation during operation of the package (in particular when the electronic component is a power semiconductor chip).

In an embodiment, a terminal, for example a source terminal, of the at least one electronic component is directly electrically connected with the at least one lead section by the component mounting area. In particular, a source pad of a gallium nitride die may be connected to at least one lead along a short path.

In an embodiment, the method comprises picking a first carrier from a singulated assembly and placing it on the second carrier. Thus, an arrangement of singulated first carriers may be subjected to a pick and place operation and may thus be assembled with an assigned second carrier. This may allow to manufacture packages with high throughput.

In an embodiment, the method comprises picking a first carrier from a tape-and-reel assembly and placing it on the second carrier. Also an arrangement of first carriers on a tape-and-reel assembly may allow to produce a plurality of packages on an industrial scale.

In an embodiment, the method comprises picking a first carrier from a bulk assembly and placing it on the second carrier. An electrically conductive connection medium may be provided in between for creating both an electrical and a mechanical connection between the two carriers.

In an embodiment, the method comprises picking a first carrier and placing it on the second carrier while the second carrier is integrally connected with at least one other second carrier. In such a configuration, the still integrally connected second carriers may be separated from each other after having assembled respective first carriers thereon, and preferably after common encapsulation.

In an embodiment, the method comprises half-etching a part of the first carrier to thereby form a thinned portion to be connected with the second carrier. This may lead to a planar configuration of the connected first and second carriers and therefore a package of compact design which can be easily assembled on a mounting base or a heat sink. Starting point may be for instance a metal plate of a homogeneous thickness. Selectively a portion, in particular a peripheral portion, of such a metal plate may be subjected to thinning by etching. Such a selective etching process may be defined by a masking of a portion of the metal plate which shall not be thinned by etching.

Alternatively, a thinning selectively of a peripheral portion of a metal plate may be accomplished by mechanical abrasion, for instance by routing.

In an embodiment, the electronic component is configured as a power semiconductor chip. Thus, the electronic component (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide or gallium nitride). A semiconductor power chip may comprise one or more field effect transistors, diodes, inverter circuits, half-bridges, full-bridges, drivers, logic circuits, further devices, etc.

As substrate or wafer forming the basis of the electronic components, a semiconductor substrate, preferably a silicon substrate, may be used. Alternatively, a silicon oxide or another insulator substrate may be provided. It is also possible to implement a germanium substrate or a III-V-semiconductor material. For instance, exemplary embodiments may be implemented in gallium nitride or silicon carbide technology.

For the encapsulating, a plastic-like material or a ceramic material which may be subsidized by encapsulant additives such as filler particles, additional resins or others may be used.

The above and other objects, features and advantages will become apparent from the following description and the appended claims, taken in conjunction with the accompanying drawings, in which like parts or elements are denoted by like reference numbers.

Before exemplary embodiments will be described in more detail referring the figures, some general to considerations will be summarized based on which exemplary embodiments have been developed.

For high performance, packages, for instance packages based on big gallium nitride dies, a high efficiency and a low Rdson 10 drain-to-source on-state resistance) are desired.

A conventional challenge for a bigger gallium nitride chip is that these chips require a thicker leadframe to reduce leadframe and die warpage during a reflow process using a high lead (Pb) solder alloy. For instance, a qualified leadframe thickness for a gallium nitride die may be about 0.50 mm. However, die warpage may cause High Temperature Reverse Bias (HTRB) issues. In view of this, a thicker leadframe may be used to reduce the warpage of the die-leadframe assembly.

At the same time, for instance for a half-bridge high voltage gallium nitride package, there is a limitation to the lead-to-lead pitching and lead size with the use of a thick leadframe. Normally, lead pitch may be impacted by the thickness of a leadframe. The thicker a leadframe, the bigger the lead pitch. Therefore, for a given sized leadframe, the number of leads may be reduced.

Further, more limitations of a thick leadframe to such a gallium nitride package are the following: An etching process may result in a bigger corner radius which may reduce the gap between leads. Moreover, a beveling effect of the etching process (where the midline of the leadframe thickness is wider than the top and bottom width of the leads) may also reduce the clearance between adjacent leads. Beyond this, a sawing process on a thick leadframe may further aggravate the clearance between leads due to a smearing effect of the mechanical sawing process. In addition, a minimum lead width and lead pitch that can used as per design guideline of an etched 0.50 mm thick leadframe are 0.40 mm and 1.0 mm, respectively. To increase the pin count, the package size needs to be increased. Moreover, a large corner radius may result in copper remaining at the corner of the sawn package. A reduction in the lead-to-lead clearance of the package is especially critical for packages for high voltage applications, wherein creepage distances needs to be considered in the design.

A conventional solution of such issues is an increase of the package size to increase the pin count. The increase in package size will, however, increase the package manufacturing effort. Conventionally, it may also be possible to increase a package saw street and a sawing blade thickness, in order to move the corner radius further away from the package edge. This may, however, reduce the leadframe strip density, thereby increasing the package manufacturing effort. Another approach is the use of a thinner leadframe and conductive glue, as a replacement to high lead solder. This may use a low temperature curing temperature, thereby reducing the leadframe and die warpage. The drawback is, however, that the thermal conductivity is not as good as solder-based die-attach material. This may be critical for a gallium nitride package. Still another conventional approach is the use of a thinner leadframe and highly thermally conductive die attach material, like silver sinter, as a replacement to high lead solder. This may use a low temperature curing temperature, thereby reducing the leadframe and die warpage. A drawback of this is that the manufacturing effort of silver sinter material is much higher than solder-based die attach material.

According to an exemplary embodiment, a two-carrier package is provided which comprises an electrically conductive first carrier combined with an electrically conductive second carrier having different and synergistic properties. The first carrier may be configured for assembly of an electronic component on a component mounting area, such as a die pad. The second carrier may be provided with a lead section which may have one or more electrically conductive leads establishing a connection of an exterior of the package with another device. An electronic component or a plurality of electronic components, for instance one or more semiconductor chips, may be mounted on the component mounting area. By connecting the first carrier and the second carrier, an electric connection between the electronic component and/or the first carrier on the one hand and the lead section on the other hand may be formed. This arrangement may then be encapsulated by an encapsulant (such as an epoxy mold compound). The latter may encapsulate the electronic component(s), the first carrier with its complete sidewalls as well as only a part of the second carrier. This may be done in such a way that the lead section extends out of the encapsulant. The exterior portions of the lead section may then be used for forming an electric c connection of the interior of the package with an exterior device. Advantageously, the component-carrying first carrier may be equipped with a larger carrier thickness than the leads-including second carrier. Beneficially, the thicker first carrier can support even large electronic components (like a big gallium nitride die) without suffering from carrier bending. Simultaneously, the thinner second carrier may be formed with very small leads of the lead section for high pin count and advantageous lead pitch characteristics. Such a package architecture may be based on an advantageous combination of two carriers (which may be different leadframe substrates), with the thinner second carrier being the primary or main substrate, and the thicker first carrier functioning as secondary substrate. The use of a thin second carrier may allow the use of more pin counts and narrower lead pitch, which can address conventional lead-to-lead gap issues and copper debris at a package corner. The use of the thicker first carrier may enable the use of bigger electronic components (such as a bigger gallium nitride chip). For example, such a package can be configured as best-in-class solution for high voltage gallium nitride packages.

One intention for a dual thickness combination of two carriers may be to address the die-leadframe warpage (when using a full thin leadframe), and sawing burr (when using full thick leadframe). Also heat dissipation may be a conventional issue addressed by exemplary embodiments. In addition, also HTRB characteristics may be improved, and the risk for chip cracks for GaN chips may be reduced.

According to an exemplary embodiment, a package design (in particular for a gallium nitride semiconductor chip-type package) may be provided which may implement at the same time a thick leadframe for suppressing warpage and a thin leadframe for providing leads with high pin count. This combination of two carriers, such as leadframe substrates, may combine high performance and high reliability.

The use of the thinner carrier may allow the use of more pin counts and narrower lead pitch, which can address lead-to-lead gap issues and issues concerning copper debris at the package corner.

The use of the thicker carrier may enable the use of bigger electronic components (such as a bigger gallium nitride chip), which may ensure high performance, in particular for high voltage packages (such as high voltage gallium nitride packages).

For example, the two carriers may be embodied as two leadframe substrates. A main substrate may be in strip form, and may be the thinner leadframe, for example with 0.20 mm thickness. This main leadframe may define the lead size and lead pitch of the package. The smaller thickness of this second carrier may address the issue of narrow gap between leads and may have better capability for corner radius and lower beveling effect. This main leadframe may be the second or main carrier of the package during the assembly process.

The secondary substrate, also denoted as the first carrier, may be the thicker leadframe. This second carrier may be used as die paddle of the electronic component, such as a gallium nitride die. This first carrier may be provided in strip form or as individual pads. In strip form, the first carrier may be singulated in the assembly and be picked-and-placed on the main substrate or second carrier. In individual pads, this may be provided as tape-and-reel or in bulk form and may be fed to the pick-and-place machine or from a bowl feeder, and then be bonded on the main substrate.

For example, a method of connecting, combining or binding the two (or more) carriers may use solder paste or electrically conductive glue.

Preferably, a bonding area of the first carrier or secondary substrate may be under a half-etch region thereof, which may advantageously result in coplanar leads of the main substrate and the die paddle of the secondary substrate. An exposed die paddle of the secondary substrate may constitute the main thermal and electrical dissipation path from the encapsulated electronic component(s), for example a gallium nitride chip.

The described manufacturing architecture may also enable the formation of multichip packages in particular for high voltage gallium nitride packages. Packages according to exemplary embodiments may have excellent performance due to the possibility of using big electronic components (such as a big gallium nitride chip). Also at least one further electronic component may be assembled at the package, for instance a gate driver and/or a controller.

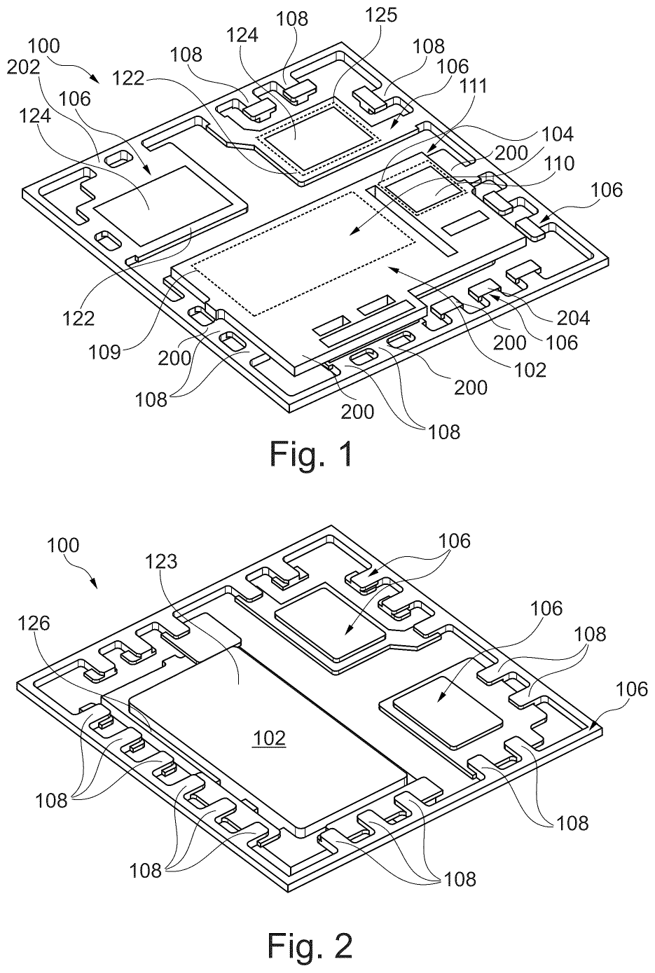

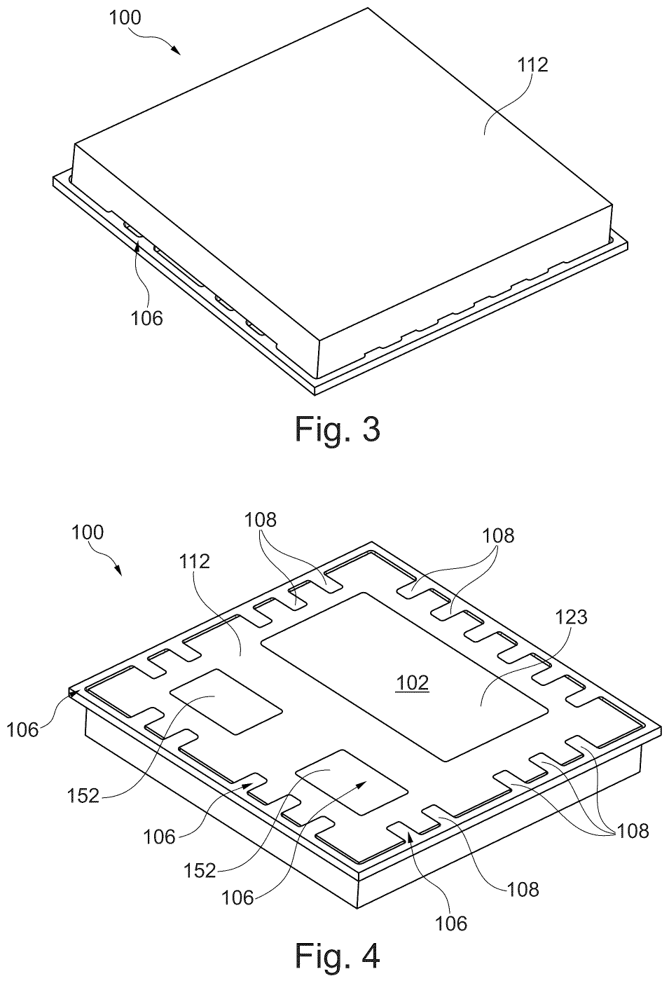

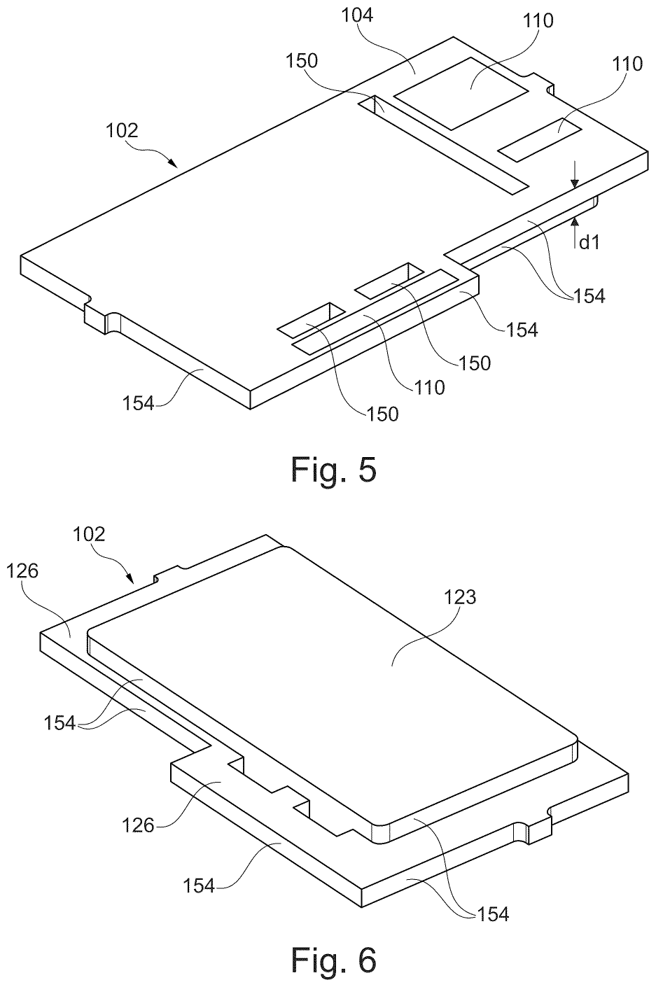

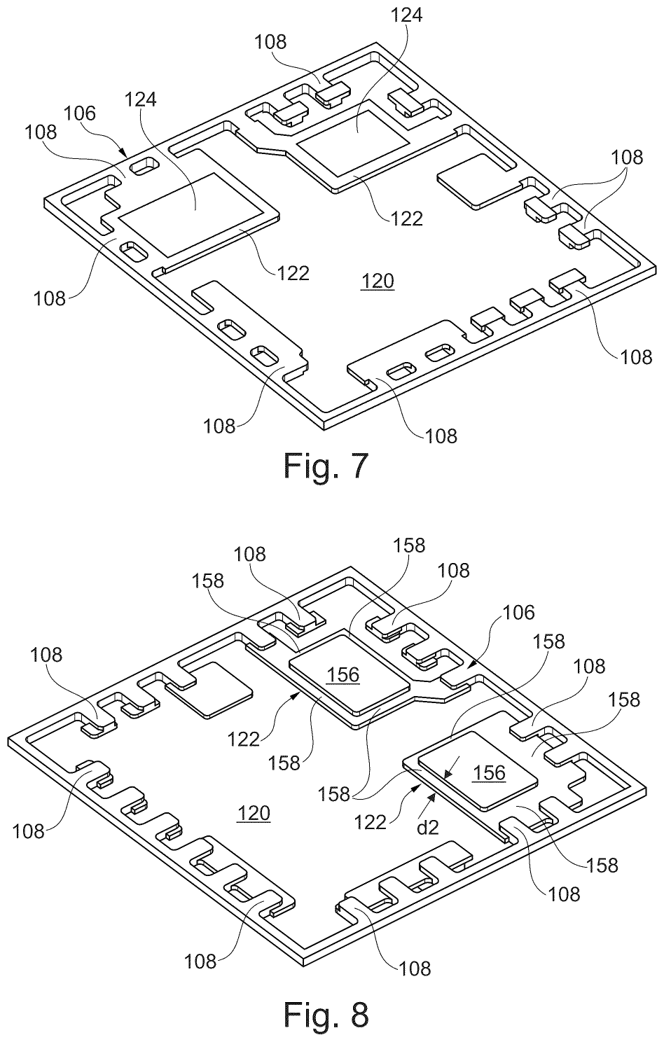

FIG. 1 illustrates a three-dimensional top view of a package 100 according to an exemplary embodiment without encapsulant 112. FIG. 2 illustrates a three-dimensional bottom view of the package 100 according to FIG. 1 without encapsulant 112. FIG. 3 illustrates a three-dimensional top view of the package 100 according to FIG. 1 with encapsulant 112. FIG. 4 illustrates a three-dimensional bottom view of the package 100 according to FIG. 1 with encapsulant 112. FIG. 5 illustrates a three-dimensional top view of a first carrier 102 of the package 100 according to FIG. 1. FIG. 6 illustrates a three-dimensional bottom view of the first carrier 102 according to FIG. 5. FIG. 7 illustrates a three-dimensional top view of a second carrier 106 of the package 100 according to FIG. 1. FIG. 8 illustrates a three-dimensional bottom view of the second carrier 106 according to FIG. 7.

Electronic components 109, 111 and 125 mounted on constituents of the package 100, as described below in further detail, are not shown in FIG. 1 to FIG. 8 with exception of FIG. 1 indicating for the sake of clarity, with dotted lines, regions where said electronic components 109, 111 and 125 are be mounted during a manufacturing process. Details concerning the assembly of said electronic components 109, 111 and 125 can be derived from FIG. 15 and FIG. 17.

FIG. 1 to FIG. 8 illustrates different aspects of the package 100, which can be a power semiconductor package having high performance and high reliability and being manufacturable with reasonable effort.

Said package 100 comprises a first carrier 102 which can be a first leadframe structure. Said first leadframe structure can be a structured metal plate, for instance comprising copper and/or aluminum and being optionally plated (for instance by NiNiP). The first carrier 102 comprises a component mounting area 104 being embodied as a die pad. As indicated by reference signs 109, 111 in FIG. 1, an electronic component 109 and an electronic component 111 can be mounted on the component mounting area 104. For example, electronic component 109 may be the biggest electronic component of the package 100 and may for instance be a power semiconductor chip, for example manufactured in gallium nitride technology. For instance, electronic component 111 may be a logic chip, such as a controller chip. In the shown embodiment, the first carrier 102 does not comprise leads. A maximum thickness d1 of the first carrier 102 is shown in FIG. 5 and can be for example 500 μm. More specifically, the first carrier 102 has a central portion 123 with said maximum thickness d1 and has a peripheral portion 126 with a smaller thickness, for example 300 μm. In particular, the thickness of the peripheral portion 123 may be larger than, smaller than or equal to below described maximum thickness d2 of the second carrier 106. For example, the thicker central portion 123 surrounded by the thinner peripheral portion 126 can be formed based on a metal plate of constant thickness by half etching or by a mechanical abrasion process. More specifically, a half-etching process may be executed on a part of the first carrier 102 to thereby form the thinned peripheral portion 126 to be connected with the lead sections 108 of the second carrier 106. After encapsulation by an encapsulant 112, the thicker central portion 123 may be exposed (see FIG. 4) which may promote efficient removal of heat generated by the encapsulated electronic components 109, 111 during operation of the package 100. In one or more surface regions of the component mounting area 104, a bonding pad 110 may be optionally formed, which may contribute to the assembly of electronic components thereon. Moreover, the first carrier 102 may comprise one or more openings 150, such as grooves or through holes, to prevent solder bleed out towards the wire bonding area and the adjacent die bonding area. Advantageously, the thick first carrier 102 has a better heat dissipation from its top surface to its bottom surface since it is made of a single integrated piece of metal, and there is no interface between two components from top to bottom.

Moreover, package 100 comprises a second carrier 106 which can be a second leadframe structure. Said second leadframe structure can be a further structured metal plate, for instance comprising copper and/or aluminum and being optionally plated (for instance by NiNiP). The second carrier 106 comprises a plurality of lead sections 108 comprising electrically conductive leads extending out of the encapsulant 112 after encapsulation (see FIG. 4). The exposed portions of the lead sections 108 allow an electric connection of an electronic periphery of the package 100 with the encapsulated components 109, 111, 125. As best seen in FIG. 1, the second carrier 106 comprises further component mounting areas 122 configured for assembling a further electronic component 125 thereon. For example, further electronic component 125 may be a logic chip. The further component mounting areas 122 may be embodied as further die pads. A maximum thickness d2 of the second carrier 106 is shown in FIG. 8 and can be for example 200 μm. More specifically, the second carrier 106 has, on the back side of the further component mounting areas 122, a central portion 156 with a larger thickness and a peripheral portion 158 with a smaller thickness (see FIG. 8). After encapsulation by encapsulant 112, surface portions 152 of the metal plate of the second carrier 106 facing away from the further component mounting areas 122 may be exposed (see FIG. 4) which may promote removal of heat generated by the encapsulated electronic component 125 during operation of the package 100. In one or more surface regions of the further component mounting areas 122, a further bonding pad 124 may be optionally formed, which may contribute to the assembly of an electronic component thereon.

As already mentioned, encapsulant 112 may encapsulate the assembled electronic components 109, 111, 125, part of the first carrier 102 including its entire sidewalls 154 but excluding a main surface of the thicker central portion 123, and part of the second carrier 106 but excluding parts of lead sections 108 and surface portions 152 (see FIG. 4). For instance, the encapsulant 112 may be a mold compound, such as an epoxy mold compound (EMC).

Exemplary embodiments may relate to leadless packages, but may also relate to leaded packages. A skilled person will understand that although until now, the above description describes leadless packages, embodiments can also cover the implementation of leaded packages. In the embodiments of FIG. 1-8, the second carrier 106 is shown as a flat leadframe, in which the leads 108 and the optional further mounting area 122 are coplanar. But it is also possible that the second carrier 106 is a leadframe with down set configuration, i.e., the leads 108 are at the position higher than the further mounting area 122. After a molding process, the bottom surface of the further mounting area 122 and the first carrier 102 may be exposed from the bottom of the package 100, but the leads 108 protrude from the sidewall of the package 100. Such an embodiment may provide the flexibility of bending the leads into a different shape to form a leaded package, which may have a better TCOB performance.)

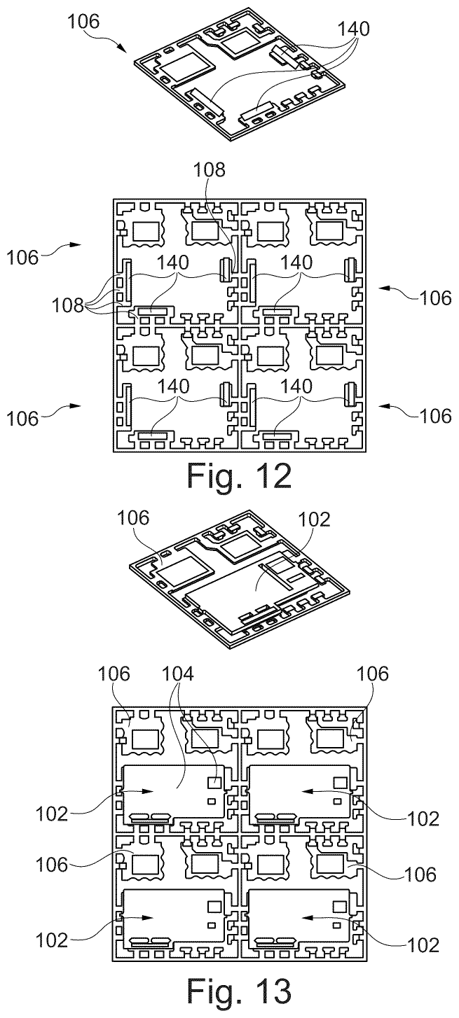

During manufacture of the package 100, the first carrier 102 may be assembled with the second carrier 106 so that the electronic components 109, 111 mounted on the first carrier 102 and/or the first carrier 102 itself is or are electrically connected with respective ones of the lead sections 108. This assembly process may be simplified by configuring the second carrier 106 with a frame shape (see FIG. 7 and FIG. 8) with a central through hole-type opening 120 in which the first carrier 102 is accommodated. The frame shape of the second carrier 106 may be obtained by forming the second carrier 106 as an annularly closed structure formed based on a planar metal plate structured to form the central through hole type opening 120. From said annularly closed rectangular structure, various functional elements of the second carrier 106 extend inwardly, in particular the lead sections 108 and the further component mounting areas 122. In this context, the first carrier 102 is assembled with the second carrier 106 by inserting the first carrier 102 in the opening 120 for establishing an electric contact with the second carrier 106. By an electrically conductive connection medium (see reference sign 140 in FIG. 12), which may be arranged on corresponding surface portions of the first carrier 102 and/or on the second carrier 106, a permanent electrical and mechanical connection between the first carrier 102 and the second carrier 106 may be established. For example, the electrically conductive connection medium 140 may be a solder, a sinter material (such as a sinter paste, for example using silver and/or copper) and/or electrically conductive glue.

As already mentioned, the first carrier 102 has a maximum first thickness d1 and the second carrier 106 has a maximum second thickness d2 which is smaller than the first thickness d1, i.e. d2<d1. This has advantages: The relatively large thickness d1 of the first carrier 102 may ensure that an even big electronic component 109 can be mounted on the component mounting area 104 without the risk of excessive bending or warpage, in particular during a reflow process. Such a big electronic component 109, for instance a power semiconductor chip manufactured in gallium nitride technology, may ensure a high performance of the package 100, and the large thickness d1 of the first carrier 102 may ensure a high reliability. Simultaneously, the relatively small maximum thickness d2 of the second carrier 106 may allow to manufacture the lead sections 108 with high pin count, small dimensions and without disturbing manufacturing artefacts. This may also contribute to the high reliability of the package 100 while meeting the needs of big electronic components 109, such as power semiconductor chips manufactured in gallium nitride technology.

Hence, the second carrier 106 is embodied as main substrate with a maximum thickness d2 of 200 μm and is embodied as a leadframe structure in strip form. Correspondingly, the first carrier 102 or secondary substrate is embodied as 500 μm thick leadframe structure which may be provided in reel form. The carriers 102, 106 are configured in a mutually matching way as combinable substrates with synergistic properties.

As already mentioned, the first carrier 102 has a thicker central portion 123 surrounded by a thinner peripheral portion 126, see FIG. 6 and FIG. 2. As best seen in FIG. 2, the thinner peripheral portion 126 of the first carrier 102 is connected with the second carrier 106. More specifically, the thinner peripheral portion 126 is connected with lead sections 108 of the second carrier 106. Advantageously, the thinner peripheral portion 126 of the first carrier 102 are assembled with the second carrier 106 so that the lead sections 108 and the thicker central portion 123 are coplanar, see FIG. 2 and FIG. 4. The main surface of the first carrier 102 visible in FIG. 2 and FIG. 4, i.e. the opposite side of the component mounting area 104 shown in FIG. 1, is coplanar with the surface of the lead sections 108 visible in FIG. 2 in FIG. 4. This main surface of the first carrier 102 (which is equal to the main surface of the central portion 123 with said maximum thickness d1) is exposed at the bottom side of the package 100, as shown in FIG. 4. The coplanar surfaces may thus be the bottom surface of the first carrier 102 according to FIG. 4 and the bottom surface of the second carrier 106 according to FIG. 4. As shown in FIG. 4, said bottom surface of the second carrier 106 includes the bottom surface of the lead sections 108 and the exposed pad-type central portions 156 of the second carrier 106. Advantageously, this leads to a planar electric contact surface of the package 100, which is the main surface of the package 100 visible in FIG. 4. This significantly simplifies to electrically and/or thermally connect said main surface with an electronic periphery (such as a mounting base like a printed circuit board) and/or thermal periphery (for example a heat sink) of the package 100.

Again referring to FIG. 4 and also to FIG. 3, manufacture of package 100 may be completed by punching the annularly closed frame structure of the second carrier 106 to separate the individual leads of the lead sections 108, if desired or required.

By exposing one main surface of the component mounting area 104, more precisely a main surface of the first carrier 102 opposing the component mounting area 104 with the electronic components 109, 111 mounted thereon, with respect to the encapsulant 112, removal of heat generated in particular by electronic component 109 during operation of the package 100 may be improved. Thus, a package 100 with high thermal performance may be obtained. In contrast to this, the opposing other main surface of the package 100, shown in FIG. 3, may be exclusively formed by material of the encapsulant 112, to reliably electrically decouple the interior of the package 100 with regard to an exterior thereof.

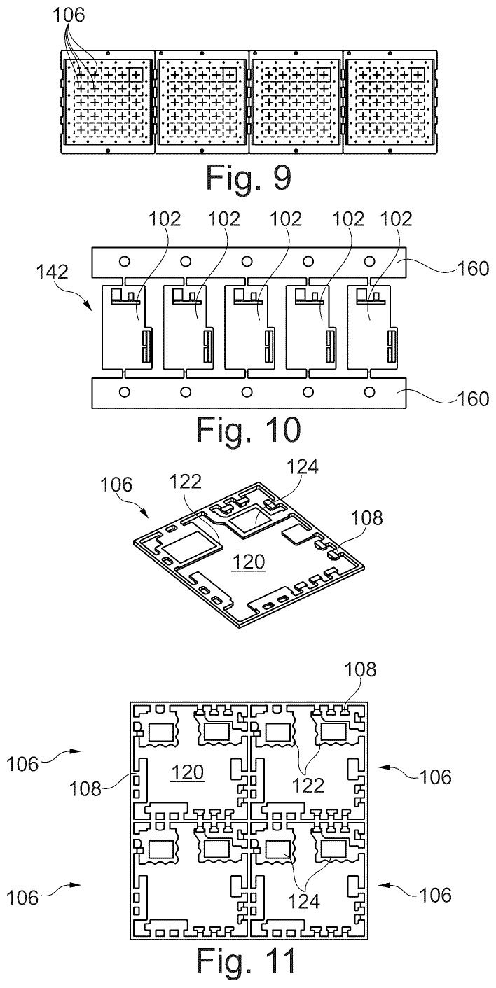

FIG. 9 illustrates an arrangement of second carriers 106 used during a batch process of manufacturing packages 100 according to an exemplary embodiment.

More specifically, an array of a plurality of second carriers 106 is illustrated which are integrally connected with each other and which are arranged in a matrix-like manner in rows and columns. Thus, a specific sample leadframe strip layout is shown in FIG. 9 on the example of a 20×5 matrix of second carriers 106. Multiple units of second carriers 106 are thus provided in one leadframe strip.

For example, it may be possible during a manufacturing process to pick a first carrier 102 and place it on one of the second carriers 106 while this second carrier 106 is integrally connected with other second carriers 106. A separation process may be executed later.

FIG. 10 illustrates an arrangement of first carriers 102 used during a batch process of manufacturing packages 100 according to an exemplary embodiment.

In FIG. 10, a plurality of first carriers 102 is shown which are arranged as a straight or linear array of first carriers 102 connected (in a separable way) by connection strips 160 with each other. Hence, the first carriers 102 are arranged as leadframe structures in reel layout.

During a package manufacturing process, it may be possible to pick a pad-shaped first carrier 102 from tape-and-reel assembly 142 and place it on a second carrier 106.

It may also be possible to pick a strip-shaped first carrier 102 from a singulated assembly and place it on the second carrier 106. Furthermore, it may be possible to pick a pad-shaped first carrier 102 from a bulk assembly and place it on the second carrier 106. With all of these methods, a high throughput on an industrial scale may be achieved.

FIGS. 11 to 21 illustrate structures obtained during manufacturing packages 100 according to an exemplary embodiment in a batch manufacturing process.

Referring to FIG. 11, an array of second carriers 106 is shown which are still integrally connected with each other. Descriptively speaking, FIG. 11 shows a leadframe strip which may be embodied as thin leadframe with a tape at the bottom side.

Referring to FIG. 12, an electrically conductive connection medium 140 is applied on surface portions of the second carrier 106, in which surface portions a mechanical and an electrically conductive connection of the second carrier 106 with a first carrier 102 shall be established. In the shown embodiment, the electrically conductive connection medium 140 is applied to lead sections 108 on which a connection surface of the first carrier 102 will be attached. For example, the electrically conductive connection medium 140 may be a solder, a sinter material or electrically conductive glue. For instance, the electrically conductive connection medium 140 may be applied by printing or dispensing of an adhesive or a solder paste on the second carrier 106 embodied as thin leadframe.

Referring to FIG. 13, a respective first carrier 102 is attached on a respective second carrier 106 in a multi-point contact region at positions of the electrically conductive connection medium 140. Thus, FIG. 13 shows the result of an attachment of the respective first carrier 102 embodied as thick leadframe in a respective opening 120 and onto the assigned second carrier 106. When taking the first carriers 102 from a tape-and-reel assembly 142 as shown in FIG. 10, the individual first carriers 102 may be singulated. More generally, the first carriers 102 may originate from a source in reel form or pre-singulated from a tape-and-reel arrangement.

The obtained arrangement may then be subjected to a curing or reflow process for establishing a permanent connection between first carrier 102 and second carrier 106 by electrically conductive connection medium 140.

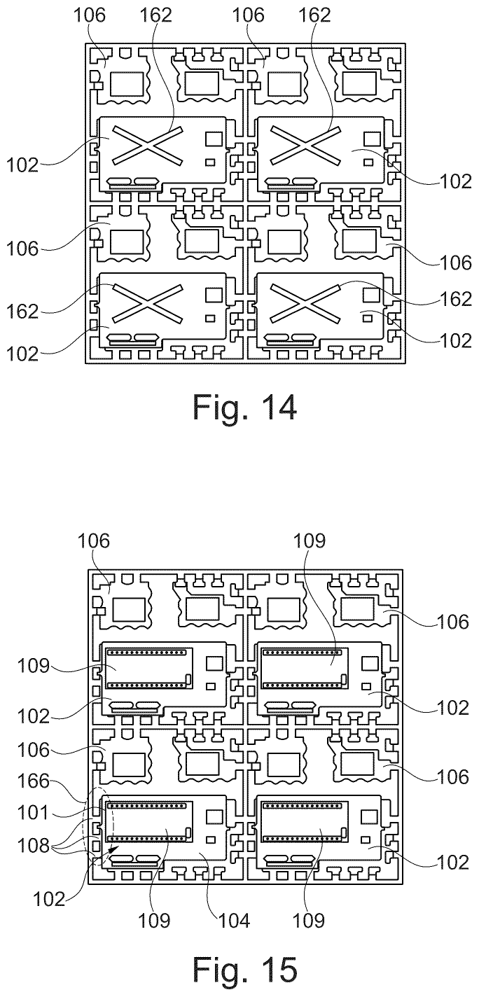

Referring to FIG. 14, the subsequent assembly of big electronic components 109 may then be prepared. This may be accomplished by providing further electrically conductive connection medium 162 to surface portions of the component mounting areas 104 of the first carriers 102 on which the big electronic components 109 are to be placed. For instance, said further electrically conductive connection medium 162 may be solder paste dispensed on the thick leadframe constituting the respective first carrier 102.

Referring to FIG. 15, the big electronic components 109 may be assembled on the further electrically conductive connection medium 162 on the respective component mounting area 104 of the respective first carrier 102. For instance, the big electronic components 109 may be gallium nitride dies. Thus, FIG. 15 shows a die attach and reflow process. Thanks to the relatively large thickness d1>d2 of the first carrier 102 compared with the second carrier 106, the first carrier 102 with the big electronic component 109 thereon can be protected against excessive warpage or bending, in particular during the reflow process.

As indicated by reference sign 166 in FIG. 15, a terminal 101, for example a source terminal, of the electronic component 109 can be electrically connected with an assigned lead section 108 by the component mounting area 104. Thus, the source terminal 101 of the electronic component 109 connects to the component mounting area 104 of the first carrier 102, then via the connection medium 140 between first carrier 102 and second carrier 106, the source terminal 101 of electronic component 109 finally electrically connects to the lead section 108. In another scenario, it may be possible to directly connect the source terminal 101 of the electronic component 109 to a lead section 108 of the second carrier 106, for instance by wire bonding or a clip.

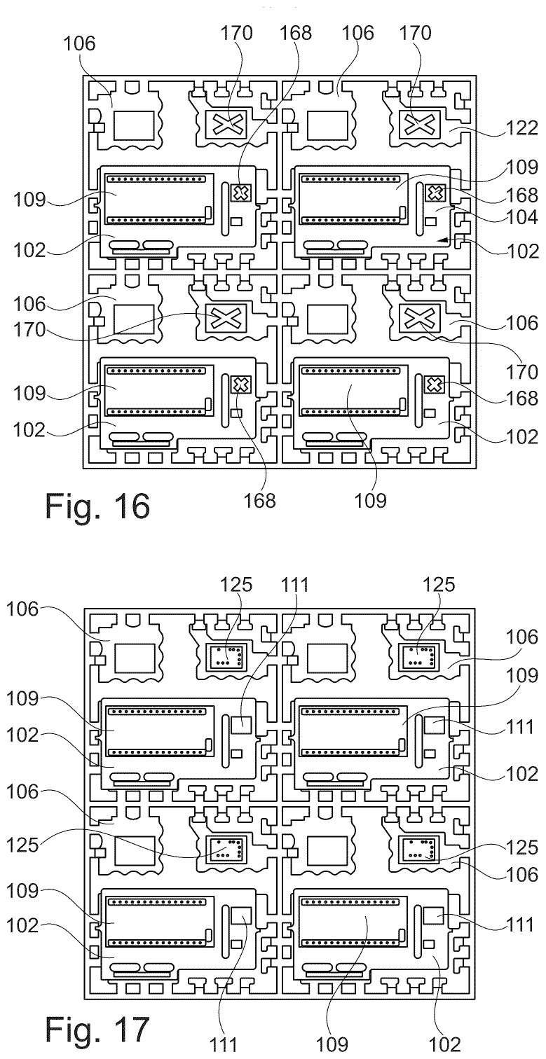

Referring to FIG. 16, the subsequent assembly of electronic components 111, 125 may then be prepared. This may be accomplished by providing further electrically conductive connection medium 168 to surface portions of the component mounting areas 104 of the first carriers 102 on which the electronic components 111 are to be placed. Moreover, further electrically conductive connection medium 170 may be applied to surface portions of the further component mounting areas 122 of the second carriers 106 on which the further electronic components 125 are to be placed. For instance, said further electrically conductive connection medium 168, 170 may be adhesive dispensed on the thick and thin leadframes constituting the respective first carrier 102 or second carrier 106.

Referring to FIG. 17, the electronic components 111 may be assembled on the further electrically conductive connection medium 168 on the respective component mounting area 104 of the respective first carrier 102. Moreover, the electronic components 125 may be assembled on the further electrically conductive connection medium 170 on the respective further component mounting area 122 of the respective second carrier 106. Thus, FIG. 17 relates to a further die attach and reflow process. For example, the electronic component 111 and the further electronic component 125 may be logic dies.

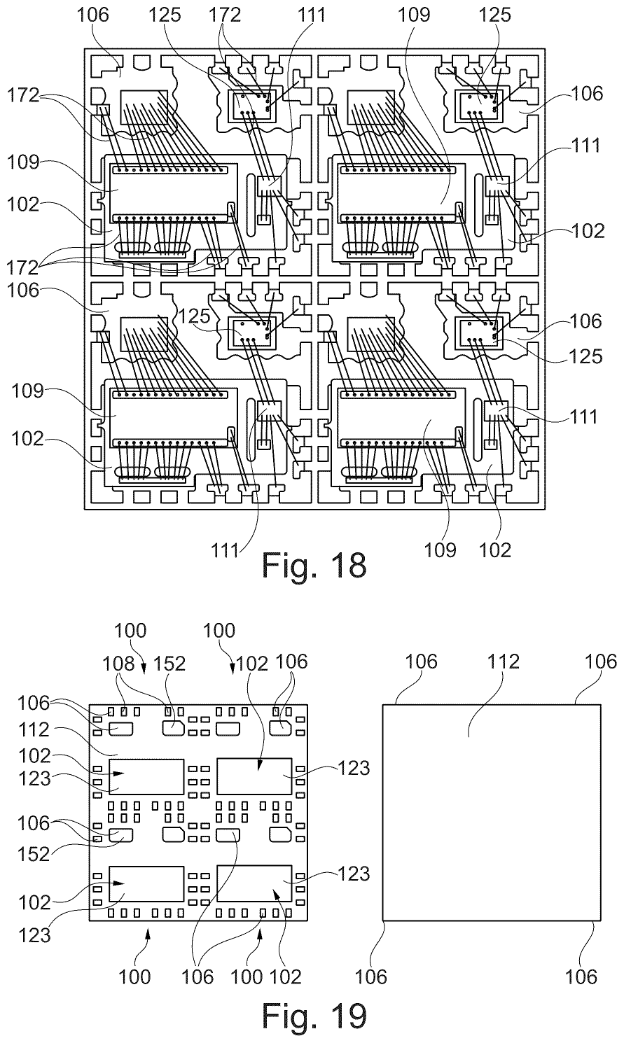

Referring to FIG. 18, electrically conductive connection elements 172 may be formed for interconnecting the electronic components 109, 111, 125 with each other and/or with the first carrier 102 and the second carrier 106, in particular with its lead sections 108. In the shown embodiment, the electrically conductive connection elements 172 may be bond wires or bond ribbons, alternatively they may be clips. Hence, FIG. 18 illustrates a wire bonding process.

Referring to FIG. 19, the structure shown in FIG. 18 may be encapsulated by an encapsulant 112, such as a mold compound. Hence, FIG. 19 illustrates the result of a molding process. On the left-hand side of FIG. 19, a bottom surface of the obtained structure is shown. On the right-hand side of FIG. 19, a top side of the obtained structure is shown.

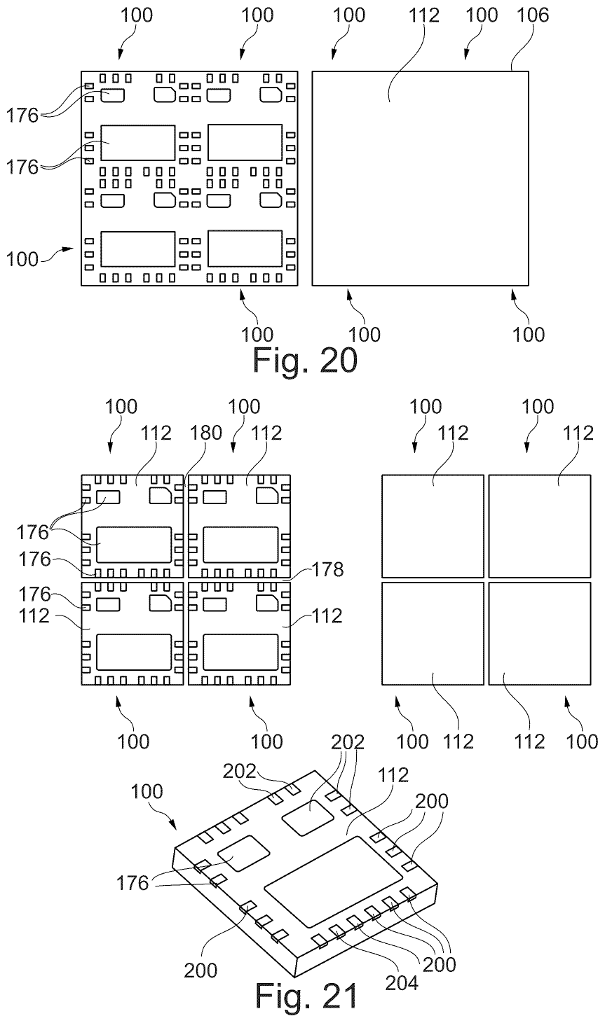

Referring to FIG. 20, a plating process is executed for plating exposed metallic surfaces of the structure shown in FIG. 19. Hence, the exposed surface portions of carriers 102, 106 shown in FIG. 19 are all plated by a plating layer 176. For example, said plating process may be a tin plating process.

Referring to FIG. 21, the structure according to FIG. 20 comprising a plurality of packages 100 being still integrally connected may be separated into individual packages 100. Separation may be along horizontal and vertical separation streets 178, 180. In particular, this may be accomplished by a saw singulation process, alternatively by laser dicing.

FIG. 1 and FIG. 21 illustrate for the example of a transistor package 100 (in particular with a power semiconductor chip embodied as gallium nitride chip) the position of a source connection 200, a drain connection 202 and a gate connection 204. This is of course only one example, and other connection architectures are possible as well.

It should be noted that the term “comprising” does not exclude other elements or features and the “a” or “an” does not exclude a plurality. Also, elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A package, comprising:
a first carrier comprising a component mounting area;
a second carrier comprising at least one lead section;
at least one electronic component mounted on the component mounting area; and
an encapsulant encapsulating at least part of the at least one electronic component, encapsulating at least part of the first carrier including encapsulating the entire sidewalls of the first carrier, and encapsulating part of the second carrier;
wherein the first carrier is assembled with the second carrier so that the at least one electronic component and/or the first carrier is electrically connected with the at least one lead section; and
wherein the first carrier has a first thickness and the second carrier has a second thickness being smaller than the first thickness.

2. The package according to claim 1, wherein the first carrier has a first thickness in a range from 300 μm to 1 mm, in particular in a range from 400 μm to 700 μm.

3. The package according to claim 1, wherein the second carrier has a second thickness in a range from 50 μm to 300 μm, in particular in a range from 150 μm to 300 μm.

4. The package according to claim 1, wherein the first carrier is assembled with the second carrier by an electrically conductive connection medium, in particular a solder, a sinter material and/or electrically conductive glue.

5. The package according to claim 1, wherein the first carrier comprises a patterned and/or bent metal plate, in particular a leadframe structure.

6. The package according to claim 1, wherein the second carrier comprises a patterned and/or bent metal plate, in particular a leadframe structure.

7. The package according to claim 1, wherein the second carrier has a frame shape with an opening in which at least part of the first carrier is accommodated.

8. The package according to claim 1, wherein the first carrier is free of lead sections.

9. The package according to claim 1, wherein the second carrier comprises a further component mounting area on which at least one further electronic component is mounted.

10. The package according to claim 1, wherein the at least one further electronic component comprises a logic chip.

11. The package according to claim 1, wherein the first carrier has a thicker central portion at least partially surrounded by a thinner peripheral portion.

12. The package according to claim 1, wherein the thinner peripheral portion of the first carrier is connected with the second carrier.

13. The package according to claim 1, wherein the thinner peripheral portion of the first carrier is assembled with the second carrier so that the at least one lead section and the thicker central portion are coplanar.

14. The package according to claim 1, wherein the at least one electronic component comprises at least one of the group consisting of a gallium nitride chip, a semiconductor power chip, a transistor chip, a half-bridge chip, a driver chip, a logic chip, and a controller chip.

15. The package according to claim 1, wherein the at least one electronic component comprises at least two electronic components (109, 111) belonging to two different chip categories, for example a power chip and a logic chip.

16. The package according to claim 1, wherein at least part of the at least one lead section is exposed with respect to the encapsulant at least at a sidewall and/or at a bottom surface of the package.

17. The package according to claim 1, wherein a bottom surface of the first carrier opposing the component mounting surface is exposed at the bottom of the package.

18. The package according to claim 1, wherein a terminal, for example a source terminal, of the at least one electronic component is electrically connected with the at least one lead section by the component mounting area.

19. A method of manufacturing a package, the method comprising:
providing a first carrier comprising a component mounting area;
providing a second carrier comprising at least one lead section;
mounting at least one electronic component on the component mounting area;
assembling the first carrier with the second carrier so that the at least one electronic component and/or the first carrier is electrically connected with the at least one lead section, wherein the first carrier has a first thickness and the second carrier has a second thickness being smaller than the first thickness; and
encapsulating at least part of the at least one electronic component, encapsulating at least part of the first carrier including encapsulating the entire sidewalls of the first carrier, and encapsulating part of the second carrier by an encapsulant.

20. The method according to claim 19, wherein the method comprises at least one of the following:
picking a first carrier from a singulated assembly and placing it on the second carrier;
picking a first carrier from a tape-and-reel assembly and placing it on the second carrier;
picking a first carrier from a bulk assembly and placing it on the second carrier;
picking a first carrier and placing it on the second carrier while the second carrier is integrally connected with at least one other second carrier;
half-etching a part of the first carrier to thereby form a thinned portion to be connected with the second carrier.
